(19) United States
(12) Patent Application Publication
(10) Pub. No.: US 2021/0358919 A1
(43) Pub. Date: Nov. 18, 2021

(54) METHODS OF FORMING ELECTRONIC APPARATUS WITH TITANIUM NITRIDE CONDUCTIVE STRUCTURES, AND RELATED ELECTRONIC APPARATUS AND SYSTEMS

(71) Applicant: Micron Technology, Inc., Boise, ID (US)

(72) Inventors: Dojun Kim, Boise, ID (US); Sanket S. Kelkar, Boise, ID (US); Christopher W. Petz, Boise, ID (US); Anthony J. Kanago, Boise, ID (US); Brenda D. Kraus, Boise, ID (US); Soichi Sugiura, Bristow, VA (US)

(21) Appl. No.: 16/874,260

(22) Filed: May 14, 2020

(51) Int. Cl. H01L 27/108; H01L 29/49; H01L 21/28; C23C 16/34; C23C 16/455; C23C 16/56; C23C 16/24

(52) U.S. Cl. CPC H01L 27/10876; H01L 27/10823; H01L 29/4966; C23C 16/24; C23C 16/34; C23C 16/45553; C23C 16/56; H01L 21/28088

(57) ABSTRACT

Methods for forming microelectronic devices include forming a titanium nitride (TiN) material over a precursor structure. Forming the TiN material comprises repeating cycles of flowing a titanium-including gas adjacent the precursor structure; flowing a reducing gas over the precursor structure; flowing a nitrogen-including gas over the precursor structure; and, before and after flowing the nitrogen-including gas, purging gas. Related microelectronic device and related electronic systems are also described.

### TECHNICAL FIELD

Embodiments of the disclosure relate to the field of microelectronic device design and fabrication. More particularly, the disclosure relates to methods for forming microelectronic devices (e.g., semiconductor devices, such as memory devices) having conductive structures comprising titanium nitride (TiN), to relate electronic apparatus, and to related systems.

### BACKGROUND

Integrated circuit designs are continually being scaled down in size in efforts to increase the number of electronic devices that can occupy a given footprint, to reduce power consumption, and to increase operational speed. With each passing generation, electronic devices tend to get smaller and more densely packed, raising a number of challenges for integration, including challenges in the methods for fabricating small, densely-packed structures (e.g., conductive structures, such as access lines (e.g., word lines)) of the electronic devices. Meeting those design and fabrication challenges without sacrificing electronic device performance is a particularly difficult challenge. For example, electronic devices configured as memory devices often need to exhibit sufficient performance characteristics, such as low electrical resistivity (e.g., high electrical conductivity) and low so-called “row hammer” characteristic (e.g., a measure of a memory cell's tendency to leak charge, such as via junction leakage and/or gate-induced drain leakage (GIDL), and interact electrically with a neighbor, unintentionally, which can lead to possibly changing the charge and storage of the leaking cell as well as the impacted neighboring cells of the memory device).

As an example, conductive structures—such as conductive gates (e.g., gate electrodes) of access lines (e.g., word lines) of microelectronic device structures—may be frequently operated, during operation of the microelectronic device(s), to enable frequent accessing of a row of devices (e.g., memory devices). In conventional word line metal gate structures, formed in accordance with conventional fabrication methods, the frequent operation of word line metal gates tend to cause row hammer characteristics—e.g., the introduction of parasitic coupling with adjacent, non-accessed rows of devices. Such row hammer characteristics can cause adjacent rows to interact in an undesired way to cause memory cells to unintentionally flip from one state to another state, causing errors in memory storage and reading in a “victim” row. However, with these or other conductive structures of microelectronic devices, optimizing one performance parameter of an electronic device often detrimentally impacts another performance parameter of that device. For example, conductive materials (e.g., titanium nitride (TiN)) that generally exhibit low electrical resistivity may tend to negatively impact an exhibited row hammer characteristic, at least if the material is formed according to conventional methods.

Designing and fabricating electronic devices (e.g., memory devices) and materials and structures thereof (e.g., materials and structures comprising TiN) in a manner that enables the electronic device to exhibit sufficiently low conductivity with good row hammer performance continues to present challenges.

### BRIEF DESCRIPTION OF THE DRAWINGS

FIG. 1A is a flowchart diagram of a method of forming a TiN material, in accordance with embodiments of the disclosure.

FIG. 1B is a timeline diagram of stage 106 of the method of FIG. 1A, wherein a reducing gas RG is flowed concurrently with flow of TiCl₄, the flow of TiCl₄ beginning before flow of the reducing gas RG, and the flow of the TiCl₄ ceasing before cessation of the flow of the reducing gas RG, in accordance with embodiments of the disclosure.

FIG. 1C is a timeline diagram of stage 106 of the method of FIG. 1A, wherein flow of the TiCl₄ is started and stopped before the flow of the reducing gas RG is started and stopped, in accordance with embodiments of the disclosure.

FIG. 1D is a timeline diagram of stage 106 of the method of FIG. 1A, wherein flow of the TiCl₄ is started and stopped before the flow of the reducing gas RG is started and stopped, with an intervening purge, in accordance with embodiments of the disclosure.

FIG. 1E is a timeline diagram of stage 116 of the method of FIG. 1A, wherein a cap-formation gas (CFG) is introduced to form a monolayer cap structure, in accordance with embodiments of the disclosure.

FIG. 1F is a timeline diagram of stage 116 of the method of FIG. 1A, wherein flow of the cap-formation gas CFG is followed by flow of ammonia NH₃, which flows may be repeated in cycles to form a multilayer cap structure, in accordance with embodiments of the disclosure.

FIG. 2A through FIG. 2F are cross-sectional, elevational, schematic illustrations during various stages of processing to fabricate a microelectronic device structure (illustrated in FIG. 2F) that includes a titanium nitride (TiN) material and structure, in accordance with embodiments of the disclosure, wherein the illustrations of FIG. 2A through FIG. 2F are views along an X-axis, with a Z-axis defining vertical and a Y-axis defining horizontal.

FIG. 3A through FIG. 3D are cross-sectional, elevational, schematic illustrations during various stages of processing to fabricate a microelectronic device structure that includes a titanium nitride (TiN) material and structure, wherein the microelectronic device structure may be or may include the microelectronic device structure of FIG. 2F, in accordance with embodiments of the disclosure, wherein the illustrations of FIG. 3A through FIG. 3D are views along a Y-axis, with the Z-axis defining vertical and the X-axis defining horizontal.

FIG. 4 is a schematic block diagram illustrating an electronic system in accordance with embodiments of the disclosure.

### DETAILED DESCRIPTION

Structures (e.g., microelectronic device structures), apparatus (e.g., microelectronic devices), and systems (e.g., electronic systems), according to embodiments of the disclosure, include at least one structure formed of and including titanium nitride (TiN). The TiN structures may be configured as, e.g., a conductive structure of a microelectronic device (e.g., a memory device, such as a DRAM device). For example, and without limitation, the TiN structures may be configured as a conductive electrode, a conductive gate, a conductive access line (e.g., a conductive “word line”), or other conductive structure of the microelectronic device. The TiN structure is formed through a process (e.g., an atomic layer deposition (“ALD”) process, a chemical vapor deposition (“CVD”) process, an ALD-like CVD process, a furnace process) using a reducing gas (“RG”) introduced in conjunction with introduction of a titanium-including gas (e.g., TiCl₄). A nitrogen-including gas (e.g., ammonia NH₃) is not concurrently flowed with either the titanium-including gas (e.g., TiCl₄) or the reducing gas RG. Also, the nitrogen-including gas (e.g., ammonia NH₃) is not flowed in between flow of the titanium-including gas (e.g., TiCl₄) and the reducing gas RG.

By these methods, the TiN material is formed in substantially continuous layers (e.g., films), exhibiting few or no void spaces (e.g., gaps, seams) between grains of TiN material. Therefore, the resulting TiN structures exhibit not only the low electrical resistivity (e.g., high conductivity) of TiN material, but also exhibit low row hammer characteristics, with minimal or no current leakage. Moreover, the methods of embodiments of the disclosure inhibit species (e.g., one or more halides, such as chlorine (Cl), from the reaction gases of the material-formation process) from diffusing and forming trap sites or other defects at interfaces with other materials (e.g., gate oxide material). Accordingly, the TiN material—and TiN structures—formed in accordance with embodiments of the disclosure may be conducive for forming word line metal gates of microelectronic device structures (e.g., memory devices, such as DRAM devices), namely word line metal gates.

As used herein, the term “memory device” means and includes a microelectronic device exhibiting memory functionality, but not necessarily limited to memory functionality. In other words, and by way of example only, the term “memory device” means and includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “reducing gas” means and includes a gas formulated as a reducing agent, i.e., gas including an element or compound formulated to lose (or “donate”) an electron to an electron recipient in a redox chemical reaction.

As used herein, the terms “introduce” and “introducing,” when used with respect to a gas or gases, mean and include an initial exposure of a structure or material—on which another structure or material is being formed—to such gas(es). A gas (or gases) may be “introduced” by causing the gas(es) to flow into an environment (e.g., a chamber) containing the structure or material on which the other structure or material is to be formed. Thus, the structure or material—on which another structure or material is being formed—is first exposed to the gas(es) by “introducing” the gas(es).

As used herein, the terms “flow” and “flowing,” when used with respect to a gas or gases, mean an include an initial or continued exposure of a structure or material—on which another structure material is or has been formed—to such gas(es). A gas (or gases) may be “flowed” by causing the gas(es) to pass over (e.g., “flow across”) the structure or material—on which the another structure or material is or has been formed—or by causing the gas(es) to otherwise come into sufficient contact with the structure or material—on which the another structure or material is or has been formed—so as to deposit at least one species from the gas(es) onto the other structure or material. Thus, the structure or material—on which another structure or material is being formed or has been formed—is exposed to the gas(es) by “flowing” the gas(es) over or onto the structure or material.

As used herein, the term “species” means and includes an element or elements (e.g., molecule(s), chemical group(s)) composing or derived from a material or composition. As nonlimiting examples, in a composition comprising SiH₄, each of silicon (Si) and hydrogen (H) may be referred to herein as a “species” of the SiH₄; and in a composition comprising TiCl₄, each of Ti and chlorine (Cl) may be referred to herein as a “species” of the TiCl₄, regardless of whether such species are, at the time of reference, presently within the originating material or composition or, instead, within or on another material or composition.

As used herein, the term “trace species” means and includes an element or elements, such as atoms or molecules, derived from one material or composition to be present on or within a volume of another material(s) in a trace amount, e.g., an atomic fraction (atoms of the treatment species relative to atoms of other species within the other material(s)) of from about 1×10⁻⁸ to about 1×10⁻¹, e.g., from about (0.001 to about 0.01). The trace amount may be determined based on a total volume of material(s) of an identified characteristic (e.g., material(s)) of a structure or region (e.g., a discrete region) of the structure, though the treatment species may be, e.g., concentrated at or near a surface of the material(s), concentrated at or near an interface between portions of the material(s), and/or dispersed throughout the volume (e.g., of the structure or the region of the structure).

As used herein, the term “trap site” means and refers to at least one of an under-coordinated, frustrated, or dangling bond or point defect of an atom or structure of the material comprising the trap site. For example, and without limitation, a “trap site” includes an unsatisfied valence on an atom. Due to the unsatisfied coordination or valency, the trap site may be highly reactive, and, in case of covalent bonding, the unpaired electrons of the dangling bond may react with electrons in other atoms in order to fill the valence shell of the atom. The atom with a trap site may be a free radical in an immobilized material, e.g., a solid.

As used herein, the term “opening” means a volume extending through at least one structure or at least one material, leaving a gap in that at least one structure or at least one material, or a volume extending between structures or materials, leaving a gap between the structures or materials. Unless otherwise described, an “opening” is not necessarily empty of material. That is, an “opening” is not necessarily void space. An “opening” formed in or between structures or materials may comprise structure(s) or material(s) other than that in or between which the opening or slit is formed. And, structure(s) or material(s) “exposed” within an opening or slit is (are) not necessarily in contact with an atmosphere or non-solid environment. Structure(s) or material(s) “exposed” within an opening may be adjacent or in contact with other structure(s) or material(s) that is (are) disposed within the opening.

As used herein, the term “substrate” means and includes a base material, base structure, or other construction upon which components, such as those within memory cells, are formed. The substrate may be a semiconductor substrate, a base semiconductor material on a supporting structure, a metal electrode, or a semiconductor substrate having one or more materials, structures, or regions formed thereon. The substrate may be a conventional silicon substrate or other bulk substrate including a semiconductive material. As used herein, the term “bulk substrate” means and includes not only silicon wafers, but also silicon-on-insulator (“SOI”) substrates, such as silicon-on-sapphire (“SOS”) substrates or silicon-on-glass (“SOG”) substrates, epitaxial layers of silicon on a base semiconductor foundation, or other semiconductor or optoelectronic materials, such as silicon-germanium (Si₁₋ₓGeₓ, where x is, for example, a mole fraction between 0.2 and 0.8), germanium (Ge), gallium arsenide (GaAs), gallium nitride (GaN), or indium phosphide (InP), among others. Furthermore, when reference is made to a “substrate” in the following description, previous process stages may have been utilized to form materials, structures, or junctions in the base semiconductor structure or foundation.

As used herein, the term “sacrificial,” when referring to a material or structure, means and includes a material or structure that is formed during a fabrication process but which is removed prior to completion of the fabrication process.

As used herein, the terms “horizontal” or “lateral” mean and include a direction that is parallel to a primary surface of the substrate on which the referenced material or structure is located. The width and length of a respective material or structure may be defined as dimensions in a horizontal plane. With reference to the figures, the “horizontal” direction may be perpendicular to an indicated “Z” axis and may be parallel to an indicated “X” axis and/or parallel to an indicated “Y” axis.

As used herein, the terms “vertical” or “longitudinal” mean and include a direction that is perpendicular to a primary surface of the substrate on which a referenced material or structure is located. The height of a respective material or structure may be defined as a dimension in a vertical plane. With reference to the figures, the “vertical” direction may be parallel to an indicated “Z” axis, may be perpendicular to an indicated “X” axis, and may be perpendicular to an indicated “Y” axis.

As used herein, the terms “thickness” and “thinness” mean and include a dimension in a straight-line direction that is normal to the closest surface of an immediately adjacent material or structure that is of a different composition or that is otherwise distinguishable from the material or structure whose thickness or thinness is discussed.

As used herein, the term “between” is a spatially relative term used to describe the relative disposition of one material, structure, or sub-structure relative to at least two other materials, structures, or sub-structures. The term “between” may encompass both a disposition of one material, structure, or sub-structure directly adjacent the other materials, structures, or sub-structures and a disposition of one material, structure, or sub-structure indirectly adjacent to the other materials, structures, or sub-structures.

As used herein, the term “proximate” is a spatially relative term used to describe disposition of one material, structure, or sub-structure near to another material, structure, or sub-structure. The term “proximate” includes dispositions of indirectly adjacent to, directly adjacent to, and internal to.

As used herein, the term “neighboring,” when referring to a material or structure, means and refers to a next, most proximate material or structure of an identified composition or characteristic. Materials or structures of other compositions or characteristics than the identified composition or characteristic may be disposed between one material or structure and its “neighboring” material or structure of the identified composition or characteristic. For example, a structure of material X “neighboring” a structure of material Y is the first material X structure, e.g., of multiple material X structures, that is next most proximate to the particular structure of material Y. The “neighboring” material or structure may be directly or indirectly proximate the structure or material of the identified composition or characteristic.

As used herein, the term “consistent”—when referring to a parameter, property, or condition of one structure, material, or feature in comparison to the parameter, property, or condition of another such structure, material, or feature—means and includes the parameter, property, or condition of the two such structures, materials, or features being equal, substantially equal, or about equal, at least in terms of respective portions of such structures, materials, or features. For example, two structures having “consistent” thicknesses as one another may each define a same, substantially same, or about the same thickness at X lateral distance from a feature, despite the two structures being at different elevations along the feature.

As used herein, the terms “about” and “approximately,” when either is used in reference to a numerical value for a particular parameter, are inclusive of the numerical value and a degree of variance from the numerical value that one of ordinary skill in the art would understand is within acceptable tolerances for the particular parameter. For example, “about” or “approximately,” in reference to a numerical value, may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “substantially,” when referring to a parameter, property, or condition, means and includes the parameter, property, or condition being equal to or within a degree of variance from a given value such that one of ordinary skill in the art would understand such given value to be acceptably met, such as within acceptable manufacturing tolerances. By way of example, depending on the particular parameter, property, or condition that is substantially met, the parameter, property, or condition may be “substantially” a given value when the value is at least 90.0% met, at least 95.0% met, at least 99.0% met, or even at least 99.9% met.

As used herein, reference to an element as being “on” or “over” another element means and includes the element being directly on top of, adjacent to (e.g., laterally adjacent to, vertically adjacent to), underneath, or in direct contact with the other element. It also includes the element being indirectly on top of, adjacent to (e.g., laterally adjacent to, vertically adjacent to), underneath, or near the other element, with other elements present therebetween. In contrast, when an element is referred to as being “directly on” or “directly adjacent to” another element, there are no intervening elements present.

As used herein, other spatially relative terms, such as “below,” “lower,” “bottom,” “above,” “upper,” “top,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation as depicted in the figures. For example, if materials in the figures are inverted, elements described as “below” or “under” or “on bottom of” other elements or features would then be oriented “above” or “on top of” the other elements or features. Thus, the term “below” may encompass both an orientation of above and below, depending on the context in which the term is used, which will be evident to one of ordinary skill in the art. The materials may be otherwise oriented (rotated ninety degrees, inverted, etc.) and the spatially relative descriptors used herein interpreted accordingly.

As used herein, the terms “comprising,” “including,” “having,” and grammatical equivalents thereof are inclusive or open-ended terms that do not exclude additional, unrecited elements or method steps, but these terms also include more restrictive terms “consisting of” and “consisting essentially of” and grammatical equivalents thereof. Therefore, a structure described as “comprising,” “including,” and/or “having” a material may be a structure that, in some embodiments, includes additional material(s) as well and/or a structure that, in some embodiments, does not include any other material(s). Likewise, a composition (e.g., gas) described as “comprising,” “including,” and/or “having” a species may be a composition that, in some embodiments, includes additional species as well and/or a composition that, in some embodiments, does not include any other species.

As used herein, the term “in conjunction with,” when used with respect to two or more processing stages, acts, or compositions thereof, means and refers to the processing stages, acts, or compositions being carried out, performed, or utilized in close time proximity with one another or concurrently. For example, a first composition gas introduced “in conjunction with” a second composition gas means and includes the first composition gas being introduced immediately before, during, or immediately after the second composition gas, e.g., without an intervening purge. Furthermore, as used herein, the term “in conjunction with” is an inclusive or open-ended term that does not exclude additional, unrecited processing stages, acts, or compositions thereof. Such term also includes a more restrictive term of “in conjunction with only,” which indicates an exclusion of additional, unrecited processing stages, acts, or compositions thereof.

As used herein, the term “may” with respect to a material, structure, feature, or method act indicates that such is contemplated for use in implementation of an embodiment of the disclosure and such term is used in preference to the more restrictive term “is” so as to avoid any implication that other, compatible materials, structures, features, and methods usable in combination therewith should or must be excluded.

As used herein, “and/or” includes any and all combinations of one or more of the associated listed items.

As used herein, the singular forms “a,” “an,” and “the” are intended to include the plural forms as well, unless the context clearly indicates otherwise.

As used herein, the terms “configured” and “configuration” mean and refer to a size, shape, material composition, orientation, and arrangement of a referenced material, structure, assembly, or apparatus so as to facilitate a referenced operation or property of the referenced material, structure, assembly, or apparatus in a predetermined way.

The illustrations presented herein are not meant to be actual views of any particular material, structure, sub-structure, region, sub-region, device, system, or stage of fabrication, but are merely idealized representations that are employed to describe embodiments of the disclosure.

Embodiments are described herein with reference to cross-sectional illustrations that are schematic illustrations. Accordingly, variations from the shapes of the illustrations as a result, for example, of manufacturing techniques and/or tolerances, are to be expected. Thus, embodiments described herein are not to be construed as limited to the particular shapes or structures as illustrated but may include deviations in shapes that result, for example, from manufacturing techniques. For example, a structure illustrated or described as box-shaped may have rough and/or nonlinear features. Moreover, sharp angles that are illustrated may be rounded. Thus, the materials, features, and structures illustrated in the figures are schematic in nature and their shapes are not intended to illustrate the precise shape of a material, feature, or structure and do not limit the scope of the present claims.

The following description provides specific details, such as material types and processing conditions, in order to provide a thorough description of embodiments of the disclosed apparatus (e.g., devices, systems) and methods. However, a person of ordinary skill in the art will understand that the embodiments of the apparatus and methods may be practiced without employing these specific details. Indeed, the embodiments of the apparatus and methods may be practiced in conjunction with conventional semiconductor fabrication techniques employed in the industry.

The fabrication processes described herein do not form a complete process flow for processing apparatus (e.g., devices, systems) or the structures thereof. The remainder of the process flow is known to those of ordinary skill in the art. Accordingly, only the methods and structures necessary to understand embodiments of the present apparatus (e.g., devices, systems) and methods are described herein.

Unless the context indicates otherwise, the materials described herein may be formed by any suitable technique including, but not limited to, spin coating, blanket coating, chemical vapor deposition (“CVD”), atomic layer deposition (“ALD”), plasma enhanced ALD, physical vapor deposition (“PVD”) (e.g., sputtering), or epitaxial growth. Depending on the specific material to be formed, the technique for depositing or growing the material may be selected by a person of ordinary skill in the art.

Unless the context indicates otherwise, the removal of materials described herein may be accomplished by any suitable technique including, but not limited to, etching (e.g., dry etching, wet etching, vapor etching), ion milling, abrasive planarization, or other known methods.

In referring to the drawings, like numerals refer to like components throughout. The drawings are not necessarily drawn to scale.

Methods of forming microelectronic device structures, of a microelectronic devices (e.g., a memory device, such as a DRAM device)—that include titanium nitride (TiN) material and structures—include forming the TiN material and structures according to a material-formation method in which a titanium-including gas (e.g., TiCl₄) is introduced in conjunction with a reducing gas RG (e.g., a silicon-based gas) after and/or before a nitrogen-based gas (e.g., NH₃) is introduced. Unexpectedly, such a method forms TiN in substantially continuous layers (e.g, monolayers, films), enabling a TiN structure to be formed—with successively formed TiN layers—with minimal or no void spaces that may otherwise enable current leakage (e.g., row hammer characteristics). Moreover, the TiN may be formed in a manner that species from the introduced gases do not diffuse out of the material being formed to cause trap sites that may detrimentally impact neighboring structures. Still further, the TiN material and structures, formed according to embodiments of the disclosure, may include trace species from the reducing gas, which trace species may inhibit grain growth and swelling of the TiN material during subsequent thermal processing acts.

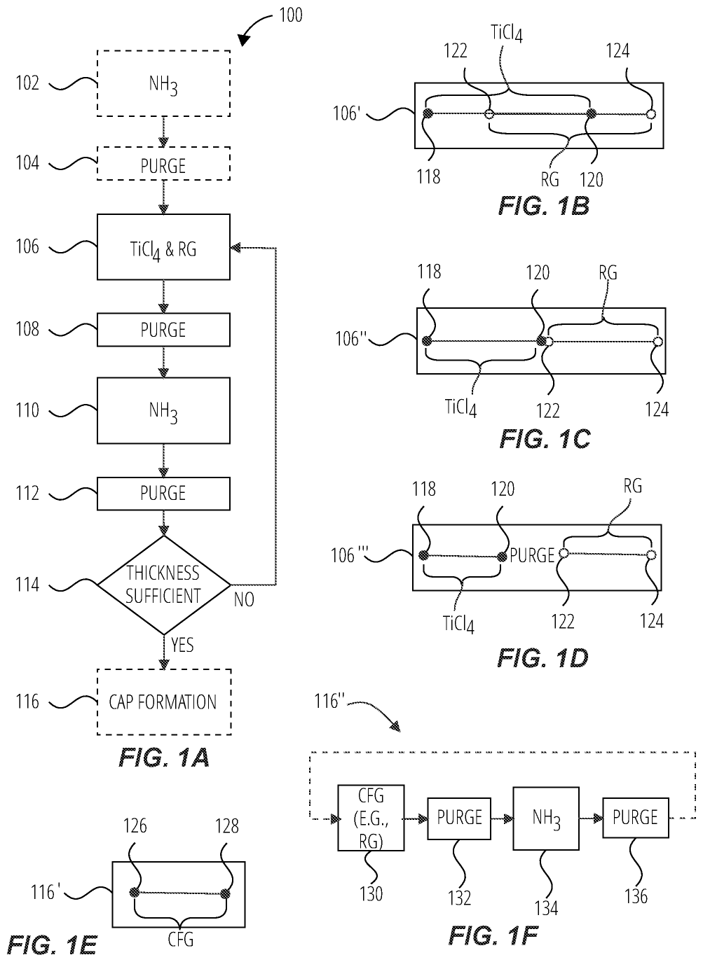

For example, FIG. 1 diagrams—in flow-chart form—a method 100 of forming a TiN material of a microelectronic device structure. The method 100 is a material-formation method (e.g., an ALD material-formation method, a CVD material-formation method), which may be carried out within one or more chambers (e.g., a deposition chamber, a diffusion chamber) configured to enable a number of gases to be flowed into the chamber (e.g., through one or more nozzles, at controllable flow rate(s), at controllable temperature, and/or at controllable pressure). The one or more chambers is also configured to enable gas from the chamber to be purged (e.g., substantially evacuated from the chamber).

With a precursor structure (e.g., a structure upon which a TiN material is to be formed) within the chamber, the method 100 may, optionally, include first exposing the precursor structure to a nitrogen-including gas (e.g., NH₃) (stage 102), which deposits nitrogen on an exposed surface of the structure. In embodiments in which the nitrogen-including gas (e.g., NH₃) is a first composition introduced to the precursor structure within a chamber (e.g., at stage 102), a purge (stage 104) is performed to substantially rid the chamber(s) of the nitrogen-including gas (e.g., NH₃).

In some embodiments, rather than beginning with introduction of the nitrogen-including gas (e.g., the NH₃) (stage 102) and the purge (stage 104)—or as a next stage subsequent to those stages—a titanium-including gas (e.g., TiCl₄) is first—or next—introduced in conjunction with introduction of a reducing gas RG (stage 106). The titanium-including gas of stage 106 (and of other stages utilizing a titanium-including gas) may be or include a titanium halide gas (e.g., TiCl₄), wherein the titanium (Ti) is accompanied by (e.g., bonded to) a halogen (e.g., chlorine (Cl)). The reducing gas RG of stage 106 (and of other stages utilizing a reducing gas RG) may be or include a silicon-based gas (e.g., a silane gas, such as SiH₄, disilane (Si₂H₆), trisilylamine (N(SiH₃)₃), trisilane (Si₃H₃)₃, an organo-silane (e.g., t-amyl silylene)). In some embodiments, the reducing gas RG of stage 106 (and of other stages utilizing a reducing gas RG) may further comprise hydrogen gas (H₂). With respect to the aforementioned t-amyl silylene, it may have the following chemical structure:

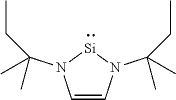

The introduction and flow of the titanium-including gas (e.g., TiCl₄) in conjunction with the reducing gas RG may not be in conjunction with introduction or flow of a nitrogen-including gas (e.g., NH₃). That is, the chamber may be free or substantially free of any nitrogen-including gas (e.g., NH₃) from the first introduction of one of the titanium-including gas (e.g., TiCl₄) or the reducing gas RG until the last stoppage of flow of the titanium-including gas (e.g., TiCl₄) and the reducing gas RG.

Exposing the precursor structure—whether already including or not yet including nitrogen atoms on a surface thereof—deposits titanium (Ti) atoms on the exposed surface(s). The concurrent or subsequent presence of the reducing gas RG (e.g., silicon-based gas) may inhibit deposition of one or more halogen-including species, such as chlorine-including species, from the titanium-including gas. Alternatively or additionally, the concurrent or subsequent presence of the reducing gas RG may promote removal (e.g., desorption) of halogen-including species from the surface(s) on which the titanium is being formed. For example, the concurrent or subsequent presence of the reducing gas RG may inhibit halogen-including compounds (e.g., HCl) from forming in the TiN material being formed and/or may promote desorption of halogen-including compounds (e.g., HCl) from the TiN material being formed.

In some embodiments, the TiN material formed may be substantially free of halogen species. For example, the TiN material may comprise less than about 0.05 at. % halogen species (e.g., about 0.04 at. % halogen species (such as about 0.04 at. % Cl), or less), as measured by, e.g., secondary-ion mass spectrometry (SIMS). The substantial absence of the halogen species may inhibit formation of voids or seams between grains of the TiN material in the resulting structure, enabling each layer (e.g., monolayer, film) of the TiN material to be formed substantially continuously. Unexpectedly, the substantially continuous layers are enabled despite the exposure of structures to the reducing gas (e.g., silicon-based gas), which may result in trace species from the reducing gas being formed in the TiN material. For example, trace amounts (e.g., less than about 1 at. %) of silicon (Si) may be included the TiN material. Even so, the TiN material may be formed substantially continuously, avoiding voids and seams that may otherwise lead to current leakage. Thus, the formed TiN material and structures may exhibit good (e.g., low) row hammer characteristics while also exhibiting low electrical resistivity as TiN material. Moreover, the substantial absence of halogen species (e.g., less than about 0.05 at. % halogen species, e.g., less than about 0.05 at. % chlorine (Cl), as measured by, e.g., SIMS) in the TiN material and structures formed may avoid such halogen species from subsequently diffusing into neighboring materials or structures to cause trap sites or other defects therein. This may further improve the performance properties of the TiN material and structures formed.

Introducing the titanium-including gas (e.g., TiCl₄) in conjunction with the reducing gas RG (stage 106) may include, in some embodiments, introducing the titanium-including gas first and continuing flow of the titanium-including gas while concurrently introducing the reducing gas RG, and/or may include, in some embodiments, introducing the titanium-including gas first followed by flow of the titanium-including gas. For example, stage 106 of FIG. 1A may include a stage 106′ illustrated in the schematic timeline of FIG. 1B, a stage 106″ illustrated in the schematic timeline of FIG. 1C, or a stage 106′″ illustrated in the schematic timeline of FIG. 1D. In each of FIG. 1B, FIG. 1C, and FIG. 1D, the introduction of the titanium-including gas (e.g, TiCl₄) is represented by flow start point 118, and the flow of such gas continues until it is ceased, represented by flow stop point 120; and the introduction of the reducing gas RG is represented by flow start point 122, and the flow of such gas continues until it is ceased, represented by flow stop point 124. The illustrated timelines are not drawn to scale, but are illustrated to illustrate the relative introduction and cessation of flow of the gases, respectively.

According to the stage 106′ of FIG. 1B, the titanium-including gas (e.g., TiCl₄) may be introduced first (at flow start point 118) and continued for a period of time (e.g., one or more seconds or minutes) before the reducing gas RG is introduced (e.g., at flow start point 122). The flow of both the titanium-including gas and the reducing gas RG may continue concurrently for another period of time (e.g., one or more seconds or minutes) before the flow of the titanium-including gas (e.g., TiCl₄) is ceased (e.g., at flow stop point 120). After ceasing the flow of the titanium-including gas (e.g., at flow stop point 120), the flow of the reducing gas RG may be continued for an additional period of time (e.g., one or more seconds or minutes) until the flow of the reducing gas RG is ceased (e.g., at flow stop point 124).

According to the stage 106″ of FIG. 1C, the titanium-including gas (e.g., TiCl₄) may be introduced first (at flow start point 118) and continue for a period of time (e.g., one or more seconds or minutes) before its flow is ceased (at flow stop point 120). After stopping flow of the titanium-including gas (e.g., TiCl₄), but without a purge (e.g., without purging gas from the chamber(s)), the reducing gas RG may be introduced (at flow start point 122) and flowed for a period of time (e.g., one or more seconds or minutes) before its flow is ceased (at flow stop point 124).

According to the stage 106′″ of FIG. 1D, the titanium-including gas (e.g., TiCl₄) may be introduced first (at flow start point 118) and continue for a period of time (e.g., one or more seconds or minutes) before its flow is ceased (at flow stop point 120). After stopping flow of the titanium-including gas (e.g., TiCl₄), a purge is carried out to substantially remove residual titanium-including gas (e.g., TiCl₄) and any other residual gases or by-product gases from the chamber(s). Then, the reducing gas RG may be introduced (at flow start point 122) and flowed for a period of time (e.g., one or more seconds or minutes) before its flow is ceased (at flow stop point 124).

In these or other embodiments, the illustrated lines between start points and stop points (e.g., between flow start point 118 and flow stop point 120, between flow start point 122 and flow stop point 124) may be continuous without breaks in the flow of the respective gas, or may be segmented into more than one start-and-stop period of gas flow, with or without an intervening purge. Nonetheless, the introduction and/or flow of the titanium-including gas (e.g., TiCl₄) is in conjunction with the introduction and/or flow of the reducing gas RG, and these introductions and flows are not in conjunction with introduction or flow of a nitrogen-including gas (e.g., NH₃). In some embodiments, a purge may be performed in between a stage that includes flow of nitrogen-including gas (e.g., NH₃) and a stage that includes flow of either or both of the titanium-including gas (e.g., TiCl₄) and/or the reducing gas RG, to ensure that the chamber(s) is(are) substantially free of gas-form nitrogen during the exposure of a structure to the titanium-including gas and the reducing gas RG.

After the exposure of the structure to the titanium-including gas (e.g., TiCl₄) in conjunction with the reducing gas RG (stage 106 of FIG. 1A, e.g., as stage 106′ of FIG. 1B, as stage 106″ of FIG. 1C, or as stage 106′″ of FIG. 1D), a purge may be performed (stage 108 of FIG. 1A). Then the nitrogen-including gas (e.g., NH₃) may be introduced and flowed (stage 110) for a period of time (e.g., one or more seconds or minutes) before another purge (stage 112). It is contemplated that, by the time the nitrogen-including gas (e.g., NH₃) is introduced at stage 110, a substantially continuous monolayer of titanium (Ti) atoms—with only trace amounts (e.g., less than about 1 at. %) of species (e.g., silicon Si) from the reducing gas RG—may have formed on the surface of the structure within the chamber. Due to the substantial absence of halogen-including species in or around the deposited titanium, halogen-including species may also be substantially absent in the deposited nitrogen, though there may be a trace amount species (e.g., silicon (Si)) from the reducing gas RG within the deposited nitrogen. Stage 106 through stage 112 may be repeated until a thickness of the deposited TiN material is as desired, as indicated by the decision box illustrated at stage 114.

The resulting TiN material may be substantially continuously formed on an underlying structure (e.g., a gate oxide material), such as with substantially continuous monolayers of titanium interleaved with substantially continuous monolayers of nitrogen, with only trace amounts of species (e.g., silicon (Si)) from the reducing gas RG. As discussed further below, the TiN material may form grains with few voids, seams, or other empty interstitial space between grains of the TiN, due to formation of the material by methods in accordance with embodiments of the disclosure. As discussed above, the substantial continuity of the material formed may be enabled by the reducing gas RG effectively preventing deposition of, or promoting desorption of, halogen-including species (e.g., HCl) in or on the deposited titanium and nitrogen material, unexpectedly even as trace amounts of species (e.g., silicon Si) from the reducing gas RG may also form in the TiN material. The absence of halogen-including species in the deposited TiN material also inhibits such halogen-including species from subsequently diffusing out of the TiN material and causing trap sites or other defects in neighboring materials or structures.

In some embodiments, after forming the TiN material (e.g., by stage 106 through stage 112 (and/or stage 114) in repetition, either with or without being preceded by stage 102 and stage 104), a cap may be formed on an exposed (e.g., upper) surface of the TiN material, as indicated at stage 116 of FIG. 1A. Forming the cap (stage 116) may include exposing the TiN material to one or more cap-formation gases CFG, which may be or include the reducing gas RG—i.e., the same reducing gas RG utilized in other stages of the method (e.g., stage 106 of FIG. 1A, such as stage 106′ of FIG. 1B, stage 106″ of FIG. 1C, or stage 106′″ of FIG. 1D)) or a different gas. Whether the reducing gas RG or another gas, the cap-formation gas CFG may include a silicon-including gas (e.g., a silane gas (SiH₄), disilane gas (Si₂H₆), dichlorosilane (DCS), SiHCl₃, SiCl₄, hexachlorodisilazane, trisilylamine (N(SiH₃)₃), trisilane (Si₃H₈), and/or an organo-silane (e.g., t-amyl silylene, for which the chemical structure may be as shown previously above)), such that the cap formed may comprise silicon. The presence of the cap may inhibit oxidation of the TiN material during subsequent processing stages in the fabrication of the microelectronic device structure.

In some embodiments, the formation of the cap (stage 116 of FIG. 1A) may be carried out as illustrated in the timeline of FIG. 1E (stage 116′), wherein one or more cap-formation gases (CFG) are introduced (at flow start point 126) and flowed (e.g., in one or more segments) for a period of time (e.g., one or more seconds or minutes) before ceasing such flow (at flow stop point 128). The period of time during which the cap-formation gas CFG is flowed may be significantly longer than (e.g., at least twice as long as, such as at least ten times as long) the period of time during which the reducing gas RG is flowed during its portion of stage 106. For example, in some embodiments the reducing gas RG may be flowed in stage 106 for about 10 seconds to about 30 seconds, while the reducing gas RG may be flowed as the cap-formation gas CFG in stage 116′ for about 30 seconds to about 1500 seconds. A purge may or may not follow cessation of the flow of the cap-formation gas(es) CFG.

In other embodiments, the formation of the cap (stage 116 of FIG. 1A) may be carried out as illustrated in the flow-chart of FIG. 1F (stage 116″), wherein one or more cap-formation gases (CFG) (e.g., the reducing gas RG) may be introduced and flowed for a period of time (e.g., one or more seconds or minutes) (stage 130), a purge may be performed (stage 132), a nitrogen-including gas (e.g., NH₃) may then be introduced and flowed (stage 134), and then another purge may be performed (stage 136). Stage 130 through stage 136 may be repeated until a thickness of the cap is as desired.

Accordingly, disclosed is a method of forming a microelectronic device. The method comprises forming a titanium nitride (TiN) material over a precursor structure. Forming the TiN material comprises repeating cycles that comprise flowing a titanium-including gas adjacent the precursor structure; flowing a reducing gas over the precursor structure; flowing a nitrogen-including gas over the precursor structure; and, before and after flowing the nitrogen-including gas, purging gas.

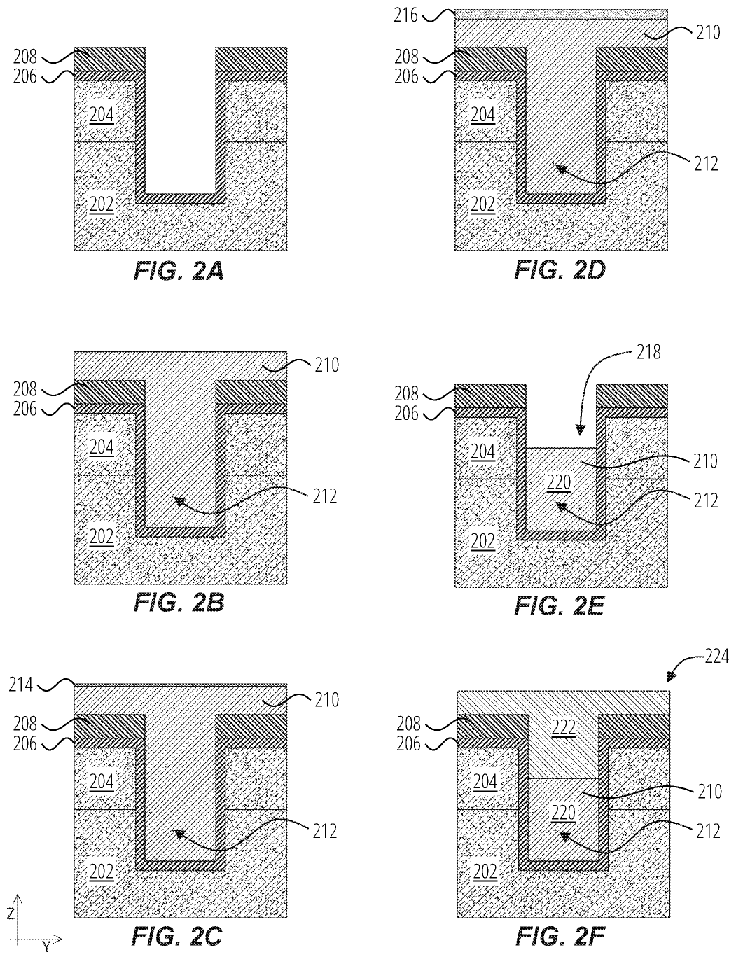

The methods discussed above may be used to form a TiN material and structure of a microelectronic device (e.g., a memory device, such as a DRAM device), such as an access line gate (e.g., a word line gate). For example, FIG. 2A through FIG. 2F illustrate various stages in a method of forming a microelectronic device structure that includes a TiN structure comprising TiN material formed according to the method 100 of FIG. 1.

With reference to FIG. 2A, a precursor structure may include a substrate 202 with a lightly-doped region 204 (collectively, e.g., a “base structure”). An opening (e.g., a trench) may be formed (e.g., etched) through the lightly-doped region 204 and into the substrate 202. A liner 206 may be conformally formed (e.g., deposited) on the lightly-doped region 204 and the substrate 202, lining the opening. The liner 206 may comprise one or more dielectric materials (e.g., an insulative oxide material, such as silicon dioxide, a silicon nitride). In some embodiments the liner 206 may be configured as a gate oxide region of the microelectronic device structure being formed. A dielectric structure 208 may be formed above the liner 206. The dielectric structure 208 may comprise the same or a different dielectric material(s) than that of the liner 206. In some embodiments, the liner 206 and the dielectric structure 208 may be a unitary structure. In these or other embodiments, the dielectric structure 208 may be, e.g., a protective material.

With reference to FIG. 2B, a TiN material 210 may be formed—according to the method 100 of FIG. 1A, e.g., in conjunction with any of FIG. 1B, FIG. 1C, or FIG. 1D and/or any of FIG. 1E or FIG. 1F—to fill the opening of FIG. 2A. By forming the TiN material 210 according to methods described above (e.g., the method 100 of FIG. 1A), the TiN material 210 includes a trace species (e.g., silicon Si), derived from the reducing gas RG (FIG. 1A), in a trace amount (e.g., less than about 1 at. % of the TiN material 210).

In some embodiments, all of the TiN material 210 may be formed by embodiments of the disclosure (e.g., the method 100 of FIG. 1A), and the trace species 212 may be distributed throughout an entire volume of the TiN material 210. In other embodiments, some of the TiN material 210 may be formed by embodiments of the disclosure (e.g., the method 100 of FIG. 1A), while other portions of the TiN material 210 may be formed by conventional or other methods. In such embodiments, the trace species 212 may be distributed throughout at least that portion of the TiN material 210 formed by the methods described herein.

By forming the TiN material 210, in whole or at least in first part, by embodiments of the disclosure (e.g., the method 100 of FIG. 1A), the TiN material 210 may be substantially free of voids or seams. The TiN material 210 may also be substantially free of halogen species. Accordingly, during subsequent processing stages and/or during operation of the microelectronic device—after completion of fabrication thereof—there may not be halogen species within the TiN material 210 (in whole or in part, e.g., as adjacent the liner 206) to diffuse out from the TiN material 210 and into adjacent materials (e.g., the liner 206). Accordingly, forming the TiN material 210—in whole or in part—according to methods disclosed herein (e.g., the method 100 of FIG. 1A), out-diffusion of halogen species, and resulting trap site formation and other defect formation in the adjacent material, may be inhibited.

With reference to FIG. 2C, in some embodiments, following formation of the TiN material 210, a cap structure may be formed on the TiN material 210 (e.g., on an upper surface of the TiN material 210). In some such embodiments in which the cap structure is formed (stage 116 of FIG. 1A) by the method of stage 116′ of FIG. 1E, a monolayer cap structure 214 may be formed on the TiN material 210. The monolayer cap structure 214 may be formed of and include, e.g., a monolayer of silicon (Si), such as in embodiments in which the cap-formation gas CFG is or includes SiH₄ or another silicon-including gas.

In some embodiments, the cap-formation stage (e.g., stage 116 of FIG. 1A, stage 116′ of FIG. 1E) may be repeated to further build up the thickness of the cap structure so as to form a multilayer cap structure 216, as illustrated in FIG. 2D, wherein “multilayer” in this context means and refers to the multilayer cap structure 216 including more than only a single monolayer of cap structure material, whether in multiple distinctive monolayers or whether as a region of material without any distinctive monolayers but a thickness greater than a single monolayer of cap structure material. The multilayer cap structure 216 may be formed of and include silicon (Si), such as in embodiments in which the cap-formation gas CFG is or includes SiH₄ or another silicon-including gas.

In other embodiments, the cap structure may be formed according to the stage 116″ of FIG. 1F, which may form the multilayer cap structure 216 of FIG. 2D to comprise silicon (e.g., in embodiments in which the cap-formation gas CFG is or includes SiH₄ or another silicon-including gas, from stage 130 of FIG. 1F) and nitrogen (e.g., from the nitrogen-including gas (e.g., NH₃) of stage 132 of FIG. 1F).

Accordingly, the cap structure (e.g., the monolayer cap structure 214 of FIG. 2C or the multilayer cap structure 216 of FIG. 2D) may comprise silicon (Si) in one monolayer or in more than one layer; or the cap structure (e.g., the multilayer cap structure 216 of FIG. 2D) may comprise both silicon (Si) and nitrogen (N), e.g., as silicon nitride (Si₃N₄). The presence of the cap structure (e.g., the monolayer cap structure 214 of FIG. 2C or the multilayer cap structure 216 of FIG. 2D) may protect the underlying TiN material 210 from oxidation during subsequent processing stages, such as those to form other features of the microelectronic device structure.

After forming the cap structure (e.g., the monolayer cap structure 214 of FIG. 2C or the multilayer cap structure 216 of FIG. 2D), or without forming the cap structure, a material-removal process may be conducted to remove the cap structure (if present) and upper portions of the TiN material 210 to form a recess 218 between the dielectric structure 208 and upper portions of the liner 206, as illustrated in FIG. 2E. After the recessing, an upper surface of the TiN material 210 may be at a lower elevation than an upper surface of each of the liner 206 and the dielectric structure 208. Thus, formed is a TiN structure 220, formed of and including the TiN material 210, the TiN structure 220 being recessed within a substrate material (e.g., the material of the substrate 202 and the lightly-doped region 204) and within a liner 206 (e.g., a gate oxide region).

With reference to FIG. 2F, an additional structure 222 may be formed (e.g., deposited) in the recess 218 and, optionally, over the dielectric structure 208 to form a microelectronic device structure 224, which may be configured as a memory device structure (e.g., a DRAM device structure). The TiN structure 220 may be configured as a word line gate electrode, e.g., a word line of a recessed access device (RAD). The TiN structure 220 may be an elongate structure, extending along the X-axis (e.g., into and out of the plane of the page on which FIG. 2E is illustrated).

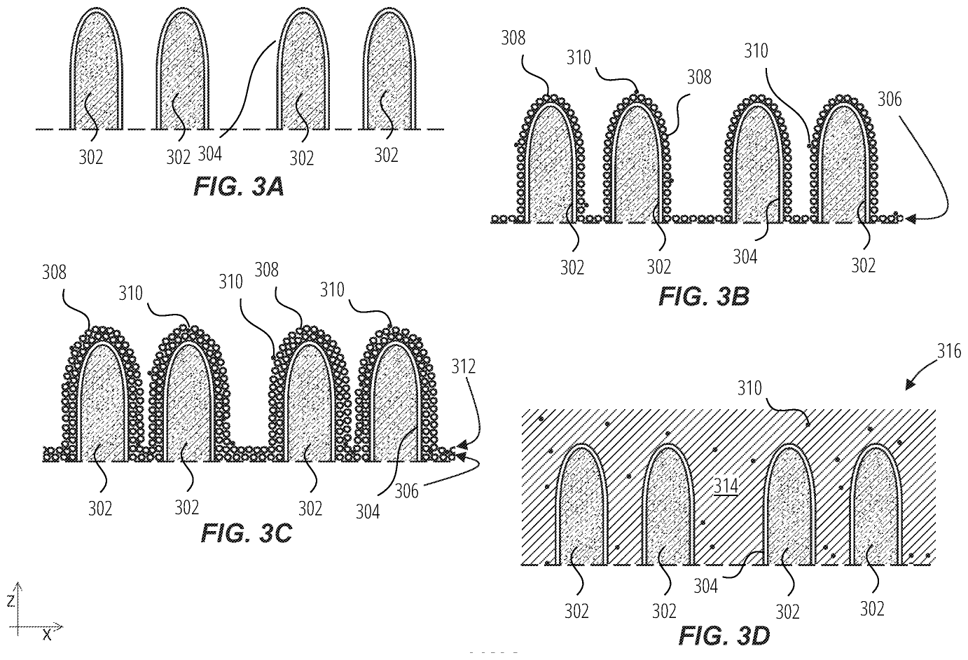

With reference to FIG. 3A through FIG. 3C, illustrated are various stages of forming a microelectronic device structure that includes fins 302 formed in a substrate material. In some embodiments, the fins 302 may be formed in the same material as the substrate 202 of FIG. 2A through FIG. 2F. In some embodiments, the fins 302 may include more than one material, such as a liner 304, such as a dielectric liner (e.g., comprising the same or different material than that of the liner 206 of FIG. 2F) on a substrate 202.

In some embodiments, the fins 302 illustrated in FIG. 3A may be only uppermost portions of fins 302 that extend downward (e.g., along with the liner 304) to define fins 302 having a large height-to-width aspect ratio (e.g., a height:width ratio of greater than about 15, e.g., greater than about 30). Additional structures and/or materials may be formed under or between the lower portions of the fins 302 (e.g., below the dashed line of FIG. 3A), such as passing lines, active lines, shallow trench isolation (STI) structures, etc., of the microelectronic device.

An uppermost portion of the fins 302 (and the liner 304, if present) may be significantly curved, tapering toward a dull point, or gradually curving along the uppermost portion of a surface of the fins 302. A TiN material (e.g., the TiN material 210 of FIG. 2F) may be formed on (e.g., directly on and between) the fins 302, according to the method 100 of FIG. 1A (e.g., in conjunction with one or more of FIG. 1B, FIG. 1C, or FIG. 1D, and one or more of FIG. 1E or FIG. 1F). Accordingly, a TiN material may be formed with a first layer 306 (FIG. 3B) of TiN grains 308 on the fins 302. The first layer 306 of the grains 308 of TiN may be formed by several monolayers of Ti and N atoms, formed according to the successive cycles of stage 106 through stage 114 of FIG. 1A. By forming the TiN material according to the method 100 of FIG. 1A, a trace species 310 (e.g., the trace species 212 of FIG. 2F) may also be present in or on the first layer 306. Then, a second layer 312 (FIG. 3C) of grains 308 of TiN may be formed on the first layer 306, as illustrated in FIG. 3C, by further cycles of stage 106 through stage 114 of FIG. 1A. Additional layers of grains 308 may be formed, successively, to build up the conformal thickness of the TiN material and form a TiN structure 314 as shown in FIG. 3D. Accordingly formed is a microelectronic device structure 316 that includes the TiN structure 314 formed on fins 302. In some embodiments, the liner 304 (e.g., a gate oxide structure) may be interposed between the fins 302 and the TiN structure 314, such that the TiN material (e.g., formed from the grains 308 and comprising the trace species 310) forming the TiN structure 314 may be directly on the liner 304.

In some embodiments, subsequent to forming the TiN material by the material-formation process described above, a thermal processing stage may be performed. In the thermal processing stage, the material of the TiN structure 314 may be subjected to a temperature exceeding about 300° C. (e.g., temperature(s) between about 300° C. to about 500° C., such as if the reducing gas RG comprises silane gas; or temperatures greater than about 500° C., such as if the reducing gas RG comprises disilane gas). The exposure to the increased heat may lead to some grain growth, e.g., merging of grains 308 (FIG. 3C) to form larger grains, yet the TiN structure 314 may be substantially free of voids or seams along grain boundaries (e.g., in interstitial space between the grains).

In comparison, a TiN material formed according to a conventional deposition process may result in a structure with relatively larger grains of TiN material and a greater quantity of voids in interstitial spaces between the larger grains. The larger grains may be the result of significant grain growth and/or swelling during thermal processing stages, which significant grain growth and/or swelling may be avoided or lessened according to embodiments of the disclosure. For example, the grains 308 (FIG. 3C) of the TiN structure 314 of the microelectronic device structure 316 of FIG. 3D—formed in accordance with embodiments of the disclosure, and before a thermal processing stage—may have an average maximum width (e.g., an average, across a selection of the grains 308 (FIG. 3C), of a maximum width of each of the grains 308) of less than about 5 nm. After the thermal processing stage, the grains of the TiN structure 314 of the microelectronic device structure 316—post thermal process—may have an average maximum width of about 10 nm, as a result of grain merging without swelling. The average maximum width of the grains post thermal process may be less than an average maximum width of the larger grains of TiN formable according to conventional methods in which no reducing gas is used in conjunction with the flow of a titanium-including gas, and in which a nitrogen-including gas may be the next introduced gas subsequent to flow of a titanium-including gas, which larger grains may be the result of grain growth and swelling during thermal processing.

In addition to the method 100 (FIG. 1A) of forming the TiN material avoiding or minimizing formation of halogen-including species within the TiN material (the presence of which halogen species may otherwise inhibit formation of continuous films of material), the smaller grain size of the grains of TiN formed in accordance with embodiments of the disclosure may further enable the formation of the TiN in substantially continuous layers (e.g., the first layer 306 of FIG. 3B, the second layer 312 of FIG. 3C), providing a substantially continuous, conformal film of TiN material on and between the fins 302 (e.g., directly on and between the liner 304). The continuous, conformal formation of the TiN material may be achieved even with fins 302 that are significantly curved at their uppermost portions. Accordingly, even as dimensions of fins 302 are decreased—with increasing device density—the TiN material (and the TiN structure 314) may be reliably formed, with consistent, continuous coverage on, over, and between fins 302, even fins with high height-to-width aspect ratios and shaper curves at the tips thereof. For example, the continuous, conformal TiN material (e.g., of the TiN structure 314) formed on one of the fins 302 may be substantially the same (e.g., in composition and structure) as the continuous, conformal TiN material (e.g., of the same or different TiN structure 314) formed on another of the fins 302.

Moreover, while a TiN material formed according to conventional methods may include voids that allow for current leakage and higher row hammer characteristics, the TiN material and the TiN structure 314 of the microelectronic device structure 316 of FIG. 3D may be substantially free of void space or seams between grains of the TiN material. Therefore, current leakage and row hammer characteristics may be inhibited.

In some embodiments, the microelectronic device structure 316 of FIG. 3D and the microelectronic device structure 224 of FIG. 2F may be structures of the same microelectronic device. That is, the microelectronic device structure 224 of FIG. 2F may be an X-axis view of structures of a microelectronic device (e.g., a memory device, such as a DRAM device), while the illustrations of FIG. 3A through FIG. 3D may be Y-axis views of structures of the same microelectronic device. For example, the TiN structure 220 of the microelectronic device structure 224 of FIG. 2F may be configured as a word line gate that intersects and passes over the fins 302 illustrated in FIG. 3A through FIG. 3D, such that the TiN structure 220 is the same as the TiN structure 314 of the microelectronic device structure 316 of FIG. 3D, though from a perpendicular, horizontal view. Likewise, the liner 206 of FIG. 2F may be another portion of the material forming the liner 304 of FIG. 3D; and the fins 302 may be defined in the same material as the substrate 202 (and, e.g., of the lightly-doped region 204) of FIG. 2F. Accordingly, the stage illustrated as FIG. 3A may coincide with that of FIG. 2A (wherein, the fins 302 may be formed to include the liner 304 as the liner 206 of FIG. 2A); and the stages illustrated in FIG. 3B through FIG. 3D may coincide with the stage illustrated in FIG. 2B.

Accordingly, disclosed is a microelectronic device. The microelectronic device comprises a conductive structure recessed within a base structure. The conductive structure comprises titanium nitride and less than about five atomic percent silicon throughout at least a portion of the titanium nitride. A dielectric liner is between the conductive structure and the base structure.

In some embodiments, the structures (e.g., conductive structures) formed of the TiN material, according to embodiments of the disclosure, may be substantially free of other conductive materials, such as being substantially free of one or more of tungsten (W), ruthenium (Ru), copper (Cu), tantalum (Ta), cobalt (Co), or molybdenum (Mo). Even so, the TiN materials and structures, formed according to the method 100 of FIG. 1A, may exhibit sufficiently low electrical resistivity and low row hammer effects to make the TiN materials and structures conducive for use in such conductive structures, of a microelectronic device, such as access lines (e.g., word lines) and/or gate electrodes of microelectronic devices (e.g., memory devices, such as DRAM devices).

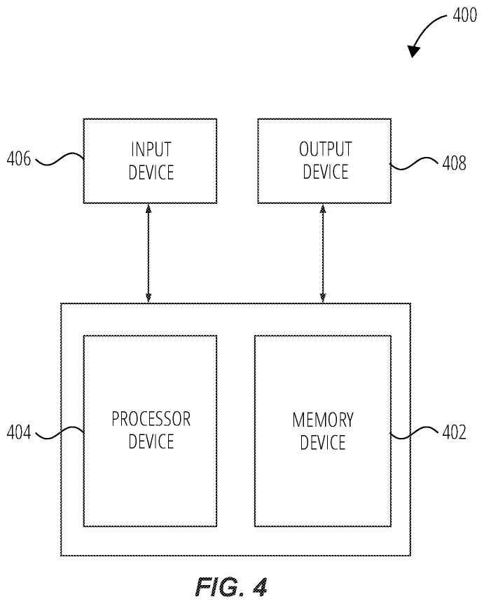

Electronic devices (e.g., semiconductor devices, memory devices (e.g., DRAM devices)) formed by methods of embodiments herein and/or including structures (e.g., microelectronic device structure 224 (FIG. 2F), microelectronic device structure 316 (FIG. 3D), or arrays of any thereof, in accordance with embodiments of the disclosure, may be used in embodiments of electronic systems of the disclosure. For example, FIG. 4 is a block diagram of an illustrative electronic system 400, according to embodiments of the disclosure. The electronic system 400 may comprise, e.g., a computer or computer hardware component, a server or other networking hardware component, a cellular telephone, a digital camera, a personal digital assistant (PDA), portable medial (e.g., music) player, etc. The electronic system 400 includes at least one memory device 402. The electronic system 400 may further include at least one processor device 404 (e.g., at least one electronic signal processor device), which may otherwise be referred to in the art as a “microprocessor.” At least one of the processor device 404 and the memory device 402 may include, e.g., an embodiment of the microelectronic device structure 224 (FIG. 2F), microelectronic device structure 316 (FIG. 3D), or arrays of any thereof. The at least one memory device 402 and the at least one processor device 404 may be combined on a “system on a chip (SoC).” Therefore, at least one of the processor device 404 and the at least one memory device 402 may include a TiN material (e.g., the TiN material 210 (FIG. 2F)), and/or one or more TiN structure (e.g., the TiN structure 220 (FIG. 2F)), formed by a method (e.g., of FIG. 1A to FIG. 1F).

The electronic system 400 may further include one or more input devices 406 for inputting information into the electronic system 400 by a user, e.g., a pointing device (e.g., a mouse), a keyboard, a touchpad, a button, a control panel, or combinations thereof. The electronic system 400 may further include one or more output devices 408 for outputting information (e.g., visual output, audio output) to a user, e.g., a monitor, a display, a printer, an audio output jack, a speaker, etc. In some embodiments, the input device 406 and the output device 408 may comprise a device configured for both input and output (e.g., a touch screen device) that can be used both to input information into the electronic system 400 and to output visual information to a user. The one or more input devices 406 and output devices 408 may communicate electrically with at least one of the memory device 402 and the processor device 404.

Accordingly, disclosed is an electronic system. The electronic system comprises an input device, an output device, a processor device, and a memory device. The processor device is operably coupled to the input device and to the output device. The memory device is operably coupled to the processor device. The memory device comprises at least one microelectronic device structure. The at least one microelectronic device structure comprises at least one access line gate structure. The at least one access line gate structure comprises titanium nitride and a silicon species dispersed throughout the titanium nitride. The silicon species constitutes less than about five atomic percent of the titanium nitride.

While the disclosed devices, structures, and methods are susceptible to various modifications and alternative forms in implementation thereof, specific embodiments have been shown by way of example in the drawings and have been described in detail herein. However, the disclosure is not intended to be limited to the particular forms disclosed. Rather, the disclosure encompasses all modifications, combinations, equivalents, variations, and alternatives falling within the scope of the disclosure as defined by the following appended claims and their legal equivalents.

What is claimed is:

1. A method of forming a microelectronic device, the method comprising:
forming a titanium nitride (TiN) material over a precursor structure, forming the TiN material comprising repeating cycles comprising:
flowing a titanium-including gas adjacent the precursor structure;
flowing a reducing gas over the precursor structure;
flowing a nitrogen-including gas over the precursor structure; and
before and after flowing the nitrogen-including gas, purging gas.

2. The method of claim 1, wherein none of the nitrogen-including gas is exposed to the precursor structure between the flow of the titanium-including gas and the flow of the reducing gas.

3. The method of claim 1, wherein flowing the titanium-including gas and flowing the reducing gas comprise flowing the reducing gas while flowing the titanium-including gas.

4. The method of claim 3, further comprising initiating flow of the titanium-including gas prior to initiating flow of the reducing gas.

5. The method of claim 4, further comprising ceasing flow of the reducing gas prior to ceasing flow of the titanium-including gas.

6. The method of claim 1, wherein flowing the titanium-including gas precedes flowing the reducing gas.

7. The method of claim 6, further comprising purging gas between flowing the titanium-including gas and flowing the reducing gas.

8. The method of claim 1, wherein:
flowing the titanium-including gas comprises flowing TiCl₄ gas; and
flowing the nitrogen-including gas comprises flowing NH₃ gas.

9. The method of claim 8, wherein flowing the reducing gas comprises flowing a silicon-including gas.

10. The method of claim 9, wherein flowing the silicon-including gas comprises flowing silane gas.

11. The method of claim 1, further comprising, after forming the titanium nitride (TiN) material over the precursor structure, forming a cap structure comprising silicon over the TiN material.

12. The method of claim 11, further comprising, removing the cap structure and a portion of the TiN material to for a TiN structure recessed relative to an upper surface of a dielectric liner of the precursor structure.

13. A microelectronic device, comprising:
a conductive structure recessed within a base structure, the conductive structure comprising titanium nitride and less than about five atomic percent silicon throughout at least a portion of the titanium nitride; and
a dielectric liner between the conductive structure and the base structure.

14. The microelectronic device of claim 13, wherein the conductive structure comprises no greater than about four atomic percent silicon throughout at least the portion of the titanium nitride.

15. The microelectronic device of claim 13, wherein the conductive structure comprises less than about 0.05 atomic percent halogen species.

16. The microelectronic device of claim 13, wherein the conductive structure comprises less than about 0.05 atomic percent chlorine species.

17. The microelectronic device of claim 13, wherein the conductive structure is substantially free of one or more of tungsten (W), ruthenium (Ru), copper (Cu), tantalum (Ta), cobalt (Co), or molybdenum (Mo).

18. The microelectronic device of claim 17, wherein the conductive structure is substantially free of the tungsten (W).

19. The microelectronic device of claim 13, further comprising fin structures comprising semiconductor material, the conductive structure disposed over and between the fin structures.

20. An electronic system, comprising:
an input device;
an output device;
a processor device operably coupled to the input device and to the output device; and
a memory device operably coupled to the processor device and comprising at least one microelectronic device structure, the at least one microelectronic device structure comprising at least one access line gate structure comprising titanium nitride and a silicon species dispersed throughout the titanium nitride, the silicon species constituting less than about five atomic percent of the titanium nitride.
